(19) United States
(12) Patent Application Publication
(10) Pub. No.: US 2026/0068068 A1
(43) Pub. Date: Mar. 5, 2026

(54) DISPLAY DEVICE, AND ELECTRONIC DEVICE INCLUDING THE DISPLAY DEVICE

(71) Applicant: Samsung Display Co., LTD., Yongin-si (KR)

(72) Inventors: JOOYOUNG KIM, Yongin-si (KR); YOUNG-JOO NAM, Yongin-si (KR)

(21) Appl. No.: 19/184,467

(22) Filed: Apr. 21, 2025

(30) Foreign Application Priority Data
Sep. 3, 2024 (KR) 10-2024-0119447

(51) Int. Cl. H05K 5/03

(52) U.S. Cl. CPC H05K 5/03

(57) ABSTRACT

A display device includes a display panel, a cover panel, a driving chip, a first circuit board, and a second circuit board. The driving chip may be on an upper surface of the display panel. The first circuit board may be on a lower surface of the cover panel. The first circuit board may include a first portion connected to the second circuit board and a second portion connected to a first end of the first portion. A first distance from a side surface of the cover panel to the first portion may be greater than a second distance from the side surface of the cover panel to the second portion. An air gap may be provided between the cover panel and the second circuit board. At least a part of the driving chip may overlap with the air gap in a plan view.

### CROSS-REFERENCE TO RELATED APPLICATION

The present application claims priority to and the benefit of Korean Patent Application No. 10-2024-0119447, filed on Sep. 3, 2024, in the Korean Intellectual Property Office, the entire disclosure of which is incorporated herein by reference.

### BACKGROUND

### 1. Field

Aspects of some embodiments of the present disclosure relate to a display device, and an electronic device including the display device.

### 2. Description of the Related Art

Electronic devices such as smartphones, digital cameras, laptop computers, navigation systems, and smart televisions, which provide images to users, include display devices for displaying such images.

A display device generates images and provides the generated images to users through a display screen.

The display panel of the display device includes a liquid crystal display panel, an organic light-emitting display panel, and the like, and various control signals and power voltages are provided to the display panel via a driving chip or similar components, which are mounted or connected to the display panel.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device in which a driving chip and a circuit board, configured to provide various control signals and power voltages to a display panel, are located, respectively, above and below the display panel.

Aspects of some embodiments of the present disclosure include a display device with relatively improved heat dissipation characteristics.

A display device according to some embodiments of the present disclosure may include a display panel, a cover panel, a driving chip, a first circuit board, and a second circuit board. According to some embodiments, the display panel may have a display area and a peripheral area defined therein. According to some embodiments, the cover panel may be on a lower surface of the display panel. According to some embodiments, the driving chip may be mounted on an upper surface of the display panel and may overlap the peripheral area in a plan view. According to some embodiments, the first circuit board may be on a lower surface of the cover panel. According to some embodiments, the second circuit board may connect the display panel and the first circuit board.

According to some embodiments, the cover panel may include a side facing the second circuit board in a first direction. According to some embodiments, the first circuit board may include a first portion connected to the second circuit board and a second portion connected to a first end of the first portion in a second direction intersecting the first direction. According to some embodiments, a first distance in the first direction from the side of the cover panel to the first portion may be greater than a second distance in the first direction from the side of the cover panel to the second portion, and an air gap, which overlaps the first portion in the first direction and overlaps the second portion in the second direction, may be provided between the cover panel and the second circuit board. According to some embodiments, at least a part of the driving chip may overlap the air gap in a plan view.

According to some embodiments, the distance in the first direction from the side of the cover panel to a distal end of the driving chip, which is farthest from the side of the cover panel, may be smaller than the first distance but greater than the second distance. According to some embodiments, a part of the boundary of the air gap may be defined by the first portion and the second portion. According to some embodiments, the driving chip may be spaced apart from the second portion in the second direction in a plan view. According to some embodiments, the second circuit board may be spaced apart from the second portion in the second direction in a plan view, and the lower surface of the cover panel may be exposed between the second circuit board and the second portion.

According to some embodiments, the first circuit board may further include a third portion. According to some embodiments, the third portion may be connected to a second end of the first portion in the second direction. According to some embodiments, a third distance in the first direction from the side of the cover panel to the third portion may be less than the first distance.

According to some embodiments, a part of the boundary of the air gap may be defined by the first portion, the second portion, and the third portion. According to some embodiments, the driving chip may be between the second portion and the third portion in the second direction in a plan view. According to some embodiments, the second circuit board may be between the second portion and the third portion in the second direction in a plan view, and the lower surface of the cover panel may be exposed between the second circuit board and the second portion and between the second circuit board and the third portion. According to some embodiments, the third distance may be equal to the second distance.

According to some embodiments, the display device may further include an adhesive layer. According to some embodiments, the adhesive layer may be between the cover panel and the first circuit board. According to some embodiments, the cover panel may include a plurality of laminated layers. According to some embodiments, among the plurality of laminated layers, a layer, which is adjacent to the adhesive layer, may include a metallic material.

A display device according to some embodiments of the present disclosure may include a display panel, a cover panel, a driving chip, a first circuit board, an adhesive layer, and a second circuit board. According to some embodiments, the display panel may have a display area and a peripheral area defined therein. According to some embodiments, the cover panel may be on a lower surface of the display panel. According to some embodiments, the driving chip may be mounted on an upper surface of the display panel and may overlap the peripheral area in a plan view. According to some embodiments, the first circuit board may be on a lower surface of the cover panel. According to some embodiments, the adhesive layer may be between the cover panel and the first circuit board. According to some embodiments, the second circuit board may connect the display panel and the first circuit board. According to some embodiments, the cover panel may include a side facing the second circuit board in a first direction. According to some embodiments, the adhesive layer may include a first portion and a second portion spaced apart from each other in a second direction intersecting the first direction. According to some embodiments, an air gap, which overlaps the first portion and the second portion in the second direction, may be provided between the cover panel and the first circuit board. At least a part of the driving chip may overlap the air gap in a plan view.

According to some embodiments, the distance in the first direction from the side of the cover panel to a distal end of the driving chip, which is farthest from the side of the cover panel, may be greater than the distance in the first direction from the side of the cover panel to the first circuit board. According to some embodiments, the air gap may extend to both ends of the first circuit board in the first direction. According to some embodiments, the driving chip may be between the first portion and the second portion in the second direction in a plan view.

According to some embodiments, the adhesive layer may further include a third portion. According to some embodiments, the third portion may connect the first portion and the second portion. According to some embodiments, a third distance in the first direction from the side of the cover panel to the third portion may be greater than a first distance from the side of the cover panel to the first portion and a second distance from the side of the cover panel to the second portion. According to some embodiments, the air gap may overlap the third portion in the first direction. According to some embodiments, the distance in the first direction from the side of the cover panel to the distal end of the driving chip, which is farthest from the side of the cover panel, may be less than the third distance.

According to some embodiments, the cover panel may include a plurality of laminated layers. According to some embodiments, among the plurality of laminated layers, a layer, which is adjacent to the adhesive layer, may include a metallic material. According to some embodiments, the first circuit board may include a plurality of laminated layers. According to some embodiments, upper layers of the plurality of laminated layers adjacent to the lower surface of the cover panel may include a cutout region overlapping the air gap in a plan view.

According to some embodiments of the present disclosure, by providing an air gap on the cover panel in a structure where the driving chip and the first circuit board are located, respectively, above and below the display panel, it may become possible to relatively improve the heat generation issue caused by the vertical overlap of the driving chip and the first circuit board.

### BRIEF DESCRIPTION OF THE DRAWINGS

These and/or other features will become more apparent and more readily appreciated from the following description of the embodiments, taken in conjunction with the accompanying drawings in which:

FIG. 1 is a plan view showing a display device according to some embodiments of the present disclosure;

FIG. 2 is a bottom view of the display device shown in FIG. 1;

FIG. 3 is a cross-sectional view taken along the line I-I of FIG. 1;

FIG. 4 is an enlarged view of portion A of FIG. 2;

FIG. 5 illustrates the coupling structure between the cover panel, the first circuit board, and the second circuit board of FIG. 3;

FIG. 6 is a first modification example of FIG. 2;

FIG. 7 is an enlarged view of portion B of FIG. 6;

FIG. 8 is a second modification example of FIG. 2;

FIG. 9 is an enlarged view of portion C of FIG. 8;

FIG. 10 is a third modification example of FIG. 2;

FIG. 11 is an enlarged view of portion D of FIG. 10;

FIG. 12 is a plan view showing a display device according to some embodiments of the present disclosure;

FIG. 13 is a bottom view of the display device shown in FIG. 12;

FIG. 14 is a cross-sectional view taken along the line I-I of FIG. 12;

FIG. 15 is a cross-sectional view taken along the line II-II of FIG. 12;

FIG. 16 is an enlarged view of portion A of FIG. 13;

FIG. 17 illustrates the coupling structure between the cover panel, the first circuit board, and the second circuit board of FIG. 14;

FIG. 18 is a modification example of FIG. 13;

FIG. 19 is a cross-sectional view taken along the line III-III of FIG. 18;

FIG. 20 is a cross-sectional view taken along the line IV-IV of FIG. 18;

FIG. 21 is an enlarged view of portion B of FIG. 18;

FIG. 22 is a modification example of FIG. 19;

FIG. 23 is an enlarged view of portion C of FIG. 22;

FIG. 24 is a block diagram of an electronic device according to some embodiments; and

FIG. 25 shows schematic diagrams of various electronic devices according to some embodiments.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

When an element is described to be “located on,” “placed on,” “arranged on,” “connected to,” or “coupled to” another element, it shall be construed as being located on, placed on, arranged on, connected to, or coupled to the other element directly but also as possibly having another element therebetween. On the other hand, if one element is described to be “directly located on,” “directly placed on,” “directly arranged on,” “directly connected to,” or “directly coupled to” another element, it shall be construed that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The term “below” or “beneath” can therefore encompass an orientation of both above and below.

Furthermore, when one device or layer is described to be “on,” “over,” “above,” and the like, another device or layer, it shall also encompass the case of yet another device or layer located on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

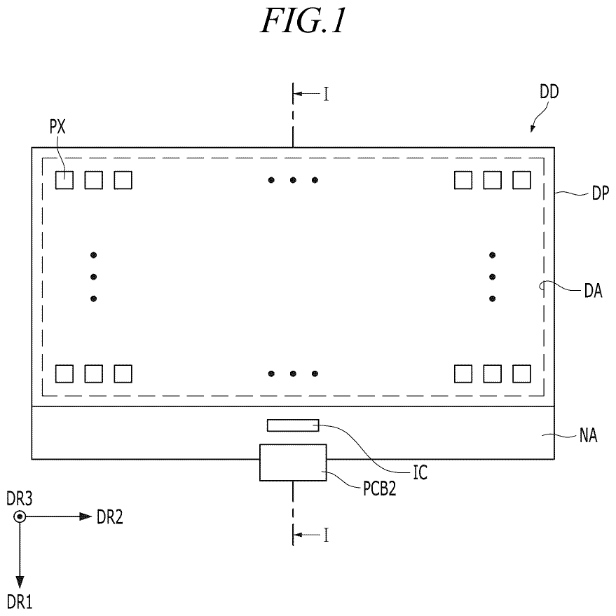

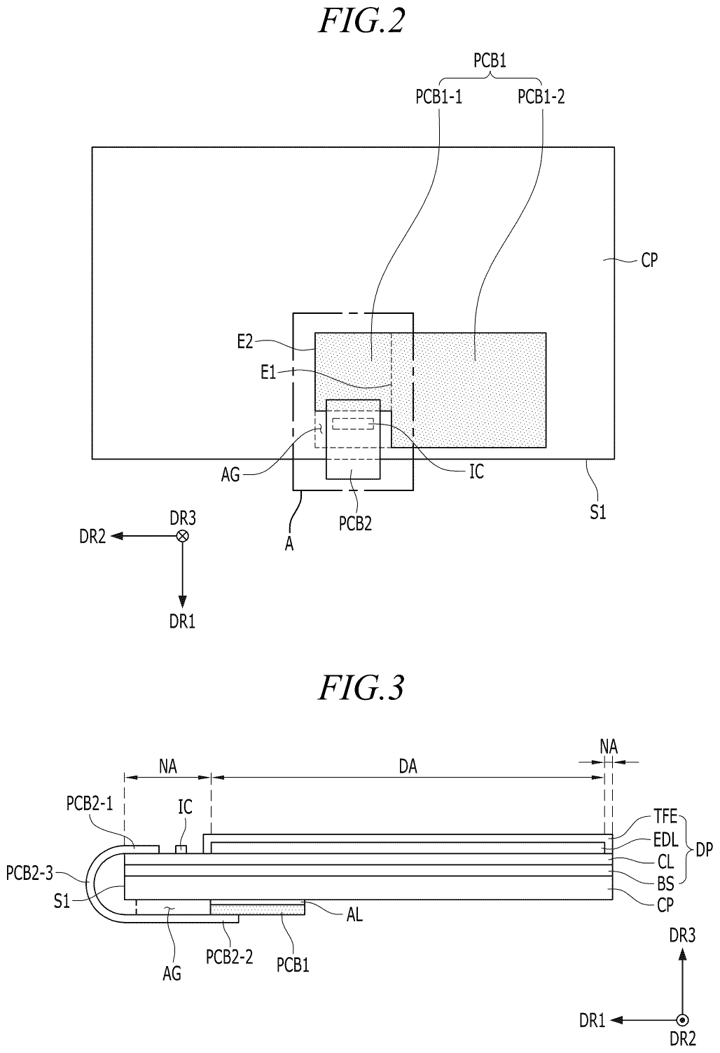

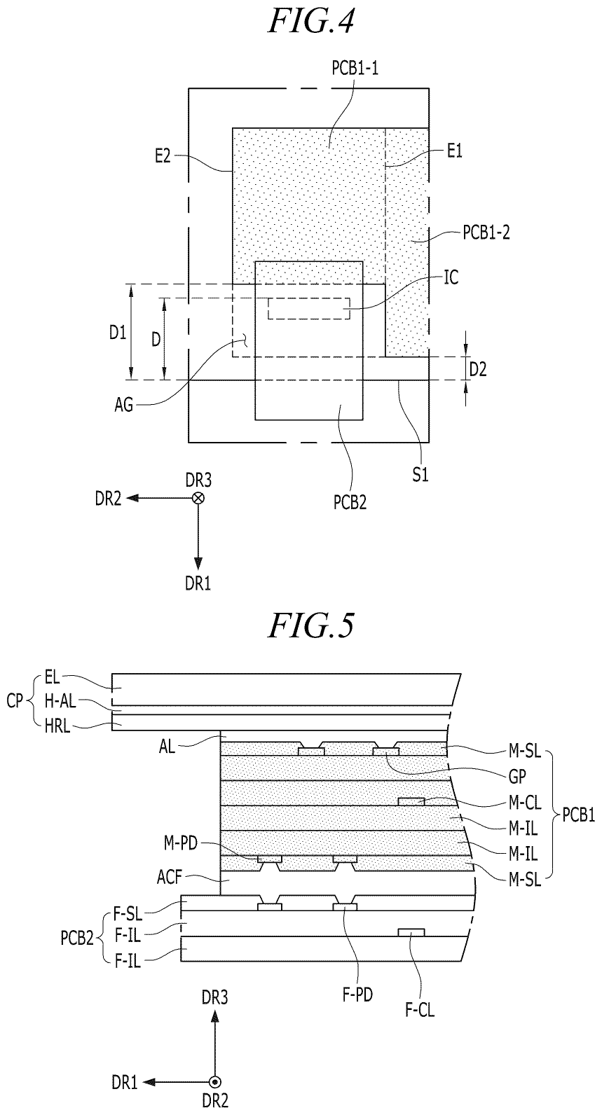

FIG. 1 is a plan view showing a display device according to some embodiments of the present disclosure; FIG. 2 is a bottom view of the display device shown in FIG. 1; FIG. 3 is a cross-sectional view taken along the line I-I of FIG. 1; and FIG. 4 is an enlarged view of portion A of FIG. 2. Referring to FIGS. 1 to 4, a display device DD according to some embodiments of the present disclosure may include a display panel DP, a cover panel CP, a driving chip IC, a first circuit board PCB1, and a second circuit board PCB2.

According to some embodiments of the present disclosure, first to third directions DR1, DR2, DR3 may be defined. The first direction DR1 may be parallel to one side of the display panel DP, and the second direction DR2 may be intersecting the first direction DR1 and parallel to another side of the display panel DP. The third direction DR3 may be perpendicular to one surface of the display panel DP. In the context of the embodiments, the expression “in a planar view” or “in a plan view” may refer to a view as seen from the third direction DR3.

The display panel DP may have a display area DA and a peripheral area NA defined therein. The display area DA is the region where images are displayed, while the peripheral area NA is the region that surrounds (e.g., in a periphery or outside a footprint of) the display area DA and where no images are displayed.

According to some embodiments, the display area DA is shown as a rectangular shape and to be surrounded by the peripheral area NA, but embodiments according to the present disclosure are not limited to what is illustrated herein, and the shapes of the display area DA and the peripheral area NA may be designed in various ways. Pixels PX, which are configured to generate images, may be arranged within the display area DA. Each pixel PX may include a light-emitting diode and a driving circuit that is configured to control the operation of the light-emitting diode. The light-emitting diode may include an organic light-emitting diode, and the driving circuit may include a thin-film transistor, but embodiments according to the present disclosure are not limited to this constitution.

The pixels PX may be arranged in a pattern (e.g., a set or predetermined pattern) and repeatedly placed within the display area DA. For example, the pixels PX may follow a Pentile™ arrangement, a Stripe arrangement, or a Diamond Pixel™ arrangement. Signal wiring configured to connect to the pixels PX may be located in the peripheral area NA. The signal wiring may include a data line connected to a source electrode of the thin-film transistor to provide a data signal, a gate line connected to a gate electrode of the thin-film transistor to provide a gate signal, and a power line connected to the light-emitting diode to apply voltage.

The display panel DP may include a substrate BS, a circuit layer CL, a display element layer EDL, and an encapsulation layer TFE. The substrate BS may be an element configured to provide a base surface on which the circuit layer CL is placed and may be made of glass, ceramic, metal, or polymer resins like polyimide. However, embodiments according to the present disclosure are not limited to what is described herein, and the substrate BS may be made of inorganic, organic, or composite materials, and may be configured with a single layer or multiple layers. The circuit layer CL may be placed on the substrate BS and may include the driving circuits of the pixels PX. The display element layer EDL may be located on the circuit layer CL and may include the light-emitting diodes of the pixels PX. The display area DA may be an area defined by the display element layer EDL in a planar view (e.g., in a plan view).

The encapsulation layer TFE may be located on the display element layer EDL to cover the display element layer EDL and to protect the light-emitting diodes of the display element layer EDL from moisture, oxygen, and/or foreign substances. The encapsulation layer TFE may include, but not limited to, a glass or synthetic resin substrate, and the encapsulation layer TFE may also be a layered structure constituted with inorganic and organic layers. According to some embodiments, additional layers such as a polarizing layer, input sensing unit, and/or cover window may be laminated on top of the encapsulation layer TFE.

The cover panel CP may be placed on a lower surface of the display panel DP. The cover panel CP may be configured to protect the display panel DP from external impacts and also to perform heat dissipating function. Detailed configurations of the cover panel CP will be described later. The driving chip IC may be mounted on an upper surface of the display panel DP and may overlap the peripheral area NA in a planar view (e.g., in a plan view). The driving chip IC may be electrically connected to the signal wiring of the display panel DP to provide data signals and/or gate signals to the display panel DP. The driving chip IC may include a source integrated circuit (Source IC) that is configured to provide data signals. The driving chip IC may further include, but not limited to, a timing controller (Tcon) and/or a level shifter. The driving chip IC may also be configured to provide electrical signals output from the display panel DP to the circuit boards PCB1, PCB2.

To facilitate signal transfer between the driving chip IC and the circuit boards PCB1, PCB2, the driving chip IC may overlap with the second circuit board PCB2 in the first direction DR1. The first circuit board PCB1 may be placed on a lower surface of the cover panel CP and connected to the display panel DP via the second circuit board PCB2. While the first circuit board PCB1 may be a rigid board, embodiments according to the present disclosure are not limited thereto. The first circuit board PCB1 may be electrically connected to the signal wiring of the display panel DP through the second circuit board PCB2 to provide control signals, power voltages, and the like to the display panel DP and/or the driving chip IC. The first circuit board PCB1 may include both active and passive devices and may have electronic components mounted thereon.

The second circuit board PCB2 may connect the upper surface of the display panel DP with a lower surface of the first circuit board PCB1. The second circuit board PCB2 may include a first portion PCB2-1, a second portion PCB2-2, and a third portion PCB2-3 and may be integrally formed with these portions. The first portion PCB2-1 may be located on the upper surface of the display panel DP and may overlap the peripheral area NA in a planar view (e.g., in a plan view). The second portion PCB2-2 may be placed on the lower surface of the first circuit board PCB1. The third portion PCB2-3, which may be curved, may connect the first portion PCB2-1 and the second portion PCB2-2. The third portion PCB2-3 may face a first side S1 of the cover panel CP in the first direction DR1. The second circuit board PCB2 may be a flexible board.

The first circuit board PCB1 may include a first portion PCB1-1 and a second portion PCB1-2, and these portions may be integrally formed. The first portion PCB1-1 may be connected to the second circuit board PCB2. The second portion PCB1-2 may be connected to a first end E1 of the first portion PCB1-1 in the second direction DR2. A first distance D1 in the first direction DR1 from the first side S1 of the cover panel CP to the first portion PCB1-1 may be greater than a second distance D2 from the first side S1 to the second portion PCB1-2. As a result, an air gap AG, which overlaps with the first portion PCB1-1 in the first direction DR1 and overlaps with the second portion PCB1-2 in the second direction DR2, may be provided between the cover panel CP and the second circuit board PCB2. According to some embodiments, the air gap AG may be defined by the first portion PCB1-1 and the second portion PCB1-2 and may refer to a space filled with air.

The air gap AG may overlap with at least a portion of the driving chip IC in a planar view (e.g., in a plan view). For example, a distance D in the first direction DR1 from the first side S1 of the cover panel CP to a distal end of the driving chip IC may be smaller than the first distance D1 but greater than the second distance D2. Here, the distal end of the driving chip IC may refer to an end farthest from the first side S1 of the cover panel CP in the first direction DR1. Moreover, the driving chip IC may be spaced apart from the second portion PCB1-2 in the second direction DR2, and the distance from the second portion PCB1-2 to the driving chip IC in the second direction DR2 may be smaller than the width of the first portion PCB1-1.

According to some embodiments, by providing the air gap AG, there can be no or a reduced overlap between the driving chip IC and the first circuit board PCB1 in a planar view (e.g., in a plan view). As a result, heat generated by the first circuit board PCB1 may be less likely to be transferred to the driving chip IC, thereby reducing the thermal load on the driving chip IC and relatively improving heat dissipation properties of the driving chip IC.

In some embodiments, the air gap AG may cover the driving chip IC in a planar view (e.g., in the plan view). In some embodiments, the driving chip IC may not overlap with the first circuit board PCB1 in a planar view (e.g., in a plan view).

In FIGS. 2 and 4, for the sake of description, the driving chip IC, which is not visible in the bottom view of the display device DD, is indicated with a dotted line. Moreover, the air gap AG may be connected to the outside through the space between the second portion PCB1-2 of the first circuit board PCB1 and the second circuit board PCB2. In other words, the lower surface of the cover panel CP may be exposed between the second portion PCB1-2 of the first circuit board PCB1 and the second circuit board PCB2. As a result, the heat dissipation characteristics owing to the air gap AG may be relatively improved. To this end, the second circuit board PCB2 may be spaced apart from the second portion PCB1-2 of the first circuit board PCB1 in the second direction DR2 in a planar view (e.g., in a plan view).

The display device DD may further include an adhesive layer AL located between the cover panel CP and the first circuit board PCB1. That is, the first circuit board PCB1 may be attached to the lower surface of the cover panel CP via the adhesive layer AL. The adhesive layer AL may be located between the cover panel CP and the first portion PCB1-1 of the first circuit board PCB1, as well as between the cover panel CP and the second portion PCB1-2 of the first circuit board PCB1, and may be integrally formed.

According to some embodiments, the second portion PCB1-2 of the first circuit board PCB1 is depicted as being connected to the first end E1 of the first portion PCB1-1 in the second direction DR2, but embodiments according to the present disclosure are not limited to what is illustrated herein, and the second portion PCB1-2 may alternatively be connected to a second end E2 of the first portion PCB1-1 in the second direction DR2.

According to some embodiments, the display device DD is depicted as including only one driving chip IC and one second circuit board PCB2, but embodiments according to the present disclosure are not limited to what is illustrated herein. Rather, the display device DD may include multiple driving chips IC and multiple second circuit boards PCB2 corresponding to the multiple driving chips IC. In such a case, the driving chips IC may be spaced apart from each other in the second direction DR2. The driving chips IC may overlap, respectively, with the second circuit boards PCB2 in the first direction DR1. The second circuit boards PCB2 may be connected to one or more first circuit boards PCB1. In such a case, the air gap AG may be provided as either multiple air gaps or a single air gap to overlap with each or all of the driving chips IC.

FIG. 5 is a diagram for illustrating the coupling structure between the cover panel, the first circuit board, and the second circuit board shown in FIG. 3. For the sake of description, both a first coupling structure between the cover panel CP and the first circuit board PCB1 and a second coupling structure between the first circuit board PCB1 and the second circuit board PCB2 are shown in a single cross-sectional view in FIG. 5, but the first coupling structure and the second coupling structure may be placed in different areas in a planar view (e.g., in a plan view).

Referring to FIG. 5, the cover panel CP may include a plurality of laminated layers EL, HRL, which may include an elastic layer EL and a heat-dissipating layer HRL. The elastic layer EL is configured to absorb external impact to protect the display panel DP from such external impacts. The elastic layer EL may include a foamed synthetic resin, for example, a foamed urethane sheet. The elastic layer EL may be placed on the lower surface of the display panel DP and may be attached to the lower surface of the display panel DP via an adhesive layer. The surface of the elastic layer EL may be provided with, but not limited to, micro-patterns (projections and/or grooves). The micro-patterns may provide a passage for air bubbles, which may form between the elastic layer EL and the display panel DP, to escape.

The heat-dissipating layer HRL is configured to absorb heat generated from the display panel DP, the driving chip IC, and/or the first circuit board PCB1 and discharge the heat. Therefore, the heat dissipation characteristics can be relatively improved. The heat-dissipating layer HRL may include a metal material with excellent thermal conductivity. Here, the metal material may include copper, gold, silver, aluminum, and the like. However, embodiments according to the present disclosure are not limited to what is described herein, and the heat-dissipating layer HRL may also include a graphite layer instead of a metal layer.

The heat-dissipating layer HRL may be placed on a lower surface of the elastic layer EL and may be attached to the lower surface of the elastic layer EL via an adhesive layer H-AL. Additionally, according to some embodiments, the cover panel CP may further include a light-shielding layer. The light-shielding layer is configured to prevent or reduce penetration of external light into the display panel DP through a rear surface of the display panel DP. The light-shielding layer may include black-colored synthetic resin, for example, a PET film.

The heat-dissipating layer HRL may be electrically connected to a ground pad GP of the first circuit board PCB1 via the adhesive layer AL. The ground pad GP may be connected to a ground pattern of an electronic component mounted on the first circuit board PCB1 through a signal line M-CL. According to some embodiments, the adhesive layer AL may be an anisotropic conductive film. The heat-dissipating layer HRL may also function as a ground layer of the first circuit board PCB1.

According to some embodiments, the first circuit board PCB1 is shown as a six-layer circuit board, including four insulating layers M-IL and two solder resist layers M-SL, but this is merely an example, and the number of layers constituting the first circuit board PCB1 is not limited to this configuration. A connection pad M-PD of the first circuit board PCB1 and an input pad F-PD of the second circuit board PCB2 may also be electrically connected via the anisotropic conductive film ACF.

According to some embodiments, the second circuit board PCB2 is shown as a three-layer circuit board, including two insulating layers F-IL and one solder resist layer F-SL, but this is merely an example, and the number of layers constituting the second circuit board PCB2 is not limited to this configuration. According to some embodiments, an output pad of the second circuit board PCB2 and a connection pad of the display panel DP may also be electrically connected via the anisotropic conductive film.

The second circuit board PCB2 may include a signal line F-CL. The signal line F-CL may be configured to connect the output pad and the input pad F-PD of the second circuit board PCB2 and transfer electrical signals and power voltage between the display panel DP and/or the driving chip IC and the first circuit board PCB1.

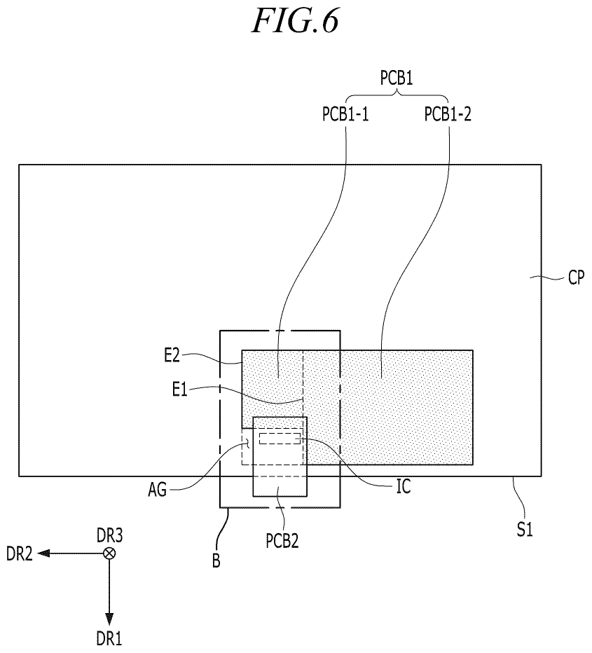

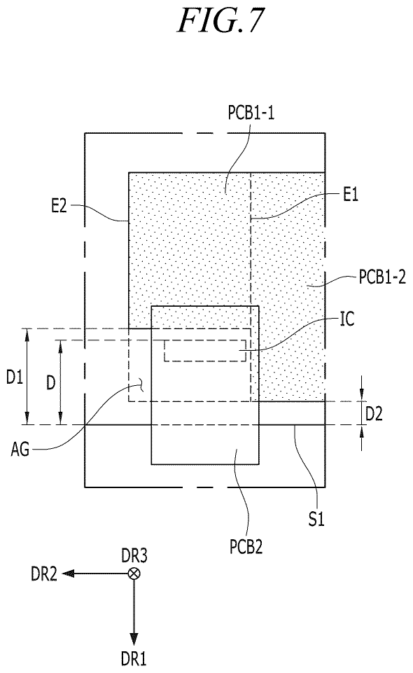

FIG. 6 is a first modification example of FIG. 2, and FIG. 7 is an enlarged view of portion B of FIG. 6. Referring to FIGS. 6 and 7, the second portion PCB1-2 of the first circuit board PCB1 may overlap with the second circuit board PCB2 in a planar view (e.g., in a plan view). According to this modification example, the second circuit board PCB2 may be supported not only by the first portion PCB1-1 of the first circuit board PCB1 but also by the second portion PCB1-2. As a result, it may become possible to maintain a sufficient distance between the cover panel CP and the second circuit board PCB2, hence ensuring the air gap AG.

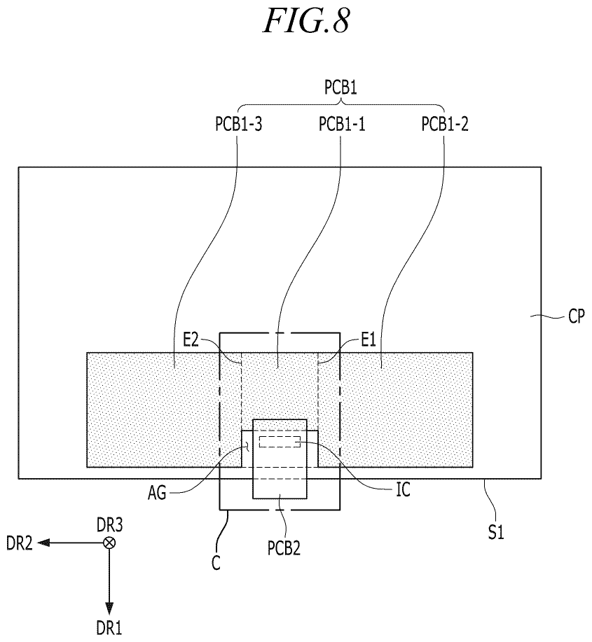

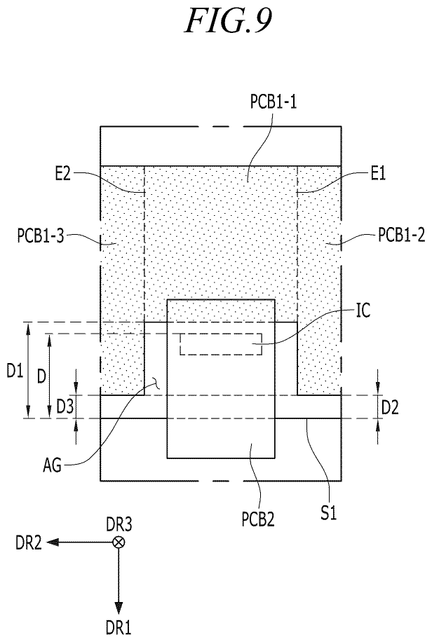

FIG. 8 is a second modification example of FIG. 2, and FIG. 9 is an enlarged view of portion C of FIG. 8. Referring to FIGS. 8 and 9, the first circuit board PCB1 may further include a third portion PCB1-3. The third portion PCB1-3 may be connected to the second end E2 of the first portion PCB1-1 in the second direction DR2. In other words, the first portion PCB1-1 may be located between the second portion PCB1-2 and the third portion PCB1-3. A third distance D3 from the first side S1 of the cover panel CP to the third portion PCB1-3 in the first direction DR1 may be smaller than the first distance D1. In this modification example, the air gap AG may be defined by the first portion PCB1-1, the second portion PCB1-2, and the third portion PCB1-3.

The driving chip IC may be located between the second portion PCB1-2 and the third portion PCB1-3 of the first circuit board PCB1 in the second direction DR2 in a planar view (e.g., in a plan view). As a result, the driving chip IC may not overlap with the first circuit board PCB1 in a planar view (e.g., in a plan view). The air gap AG may be connected to the outside between the second portion PCB1-2 of the first circuit board PCB1 and the second circuit board PCB2, as well as between the third portion PCB1-3 of the first circuit board PCB1 and the second circuit board PCB2. In other words, the lower surface of the cover panel CP may be exposed between the second portion PCB1-2 of the first circuit board PCB1 and the second circuit board PCB2, as well as between the third portion PCB1-3 of the first circuit board PCB1 and the second circuit board PCB2. As a result, it may become possible to relatively improve the heat dissipation characteristics owing to the air gap AG. To this end, the second circuit board PCB2 may be located between the second portion PCB1-2 and the third portion PCB1-3 of the first circuit board PCB1 in the second direction DR2 in a planar view (e.g., in a plan view).

The third distance D3 from the first side S1 of the cover panel CP to the third portion PCB1-3 in the first direction DR1 may be the same as the second distance D2 from the first side S1 of the cover panel CP to the second portion PCB1-2 in the first direction DR1. As a result, the first circuit board PCB1 may be formed by cutting and removing the area corresponding to the air gap AG after the substrate is manufactured.

Although it is not explicitly shown in the drawings of this modification example, the adhesive layer AL may be located between the first portion PCB1-1 of the first circuit board PCB1 and the cover panel CP, between the second portion PCB1-2 of the first circuit board PCB1 and the cover panel CP, and between the third portion PCB1-3 of the first circuit board PCB1 and the cover panel CP, and may be integrally formed.

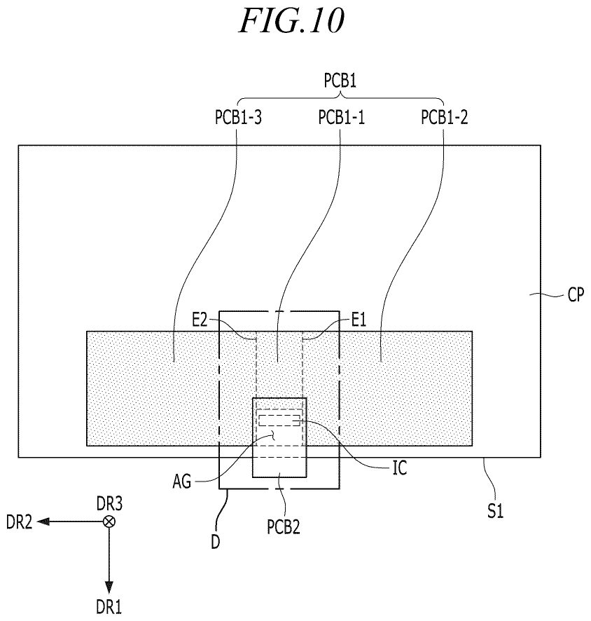

FIG. 10 is a third modification example of FIG. 2, and FIG. 11 is an enlarged view of portion D of FIG. 10. Referring to FIGS. 10 and 11, the first circuit board PCB1 may further include a third portion PCB1-3. The third portion PCB1-3 may be connected to the second end E2 of the first portion PCB1-1 in the second direction DR2. In other words, the first portion PCB1-1 may be located between the second portion PCB1-2 and the third portion PCB1-3. The third distance D3 from the first side S1 of the cover panel CP to the third portion PCB1-3 in the first direction DR1 may be smaller than the first distance D1. In this modification example, the air gap AG may be defined by the first portion PCB1-1, the second portion PCB1-2, and the third portion PCB1-3.

The driving chip IC may be located between the second portion PCB1-2 and the third portion PCB1-3 of the first circuit board PCB1 in the second direction DR2 in a planar view (e.g., in a plan view). As a result, the driving chip IC may not overlap with the first circuit board PCB1 in a planar view (e.g., in a plan view). The third distance D3 from the first side S1 of the cover panel CP to the third portion PCB1-3 in the first direction DR1 may be the same as the second distance D2 from the first side S1 of the cover panel CP to the second portion PCB1-2 in the first direction DR1. As a result, the first circuit board PCB1 may be formed by cutting and removing the area corresponding to the air gap AG after the substrate is manufactured.

In this modification example, the second portion PCB1-2 and/or the third portion PCB1-3 of the first circuit board PCB1 may overlap with the second circuit board PCB2 in a planar view (e.g., in a plan view). According to this modification example, the second circuit board PCB2 may be supported not only by the first portion PCB1-1 of the first circuit board PCB1 but also by the second portion PCB1-2 and/or the third portion PCB1-3. As a result, it may become possible to maintain a sufficient distance between the cover panel CP and the second circuit board PCB2, hence ensuring the air gap AG.

Although not explicitly shown in the drawings of this modification example, the adhesive layer AL may be located between the first portion PCB1-1 of the first circuit board PCB1 and the cover panel CP, between the second portion PCB1-2 of the first circuit board PCB1 and the cover panel CP, and between the third portion PCB1-3 of the first circuit board PCB1 and the cover panel CP, and may be integrally formed.

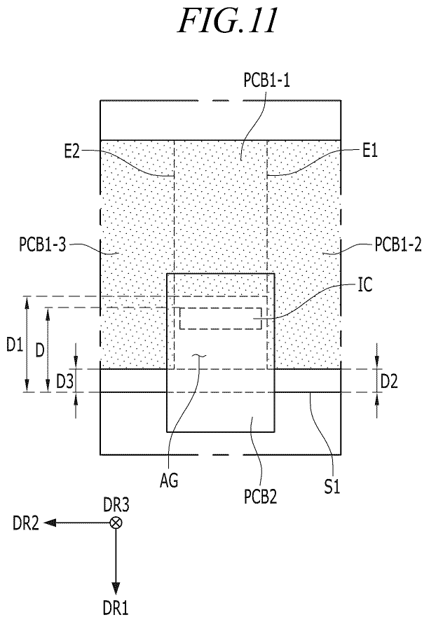

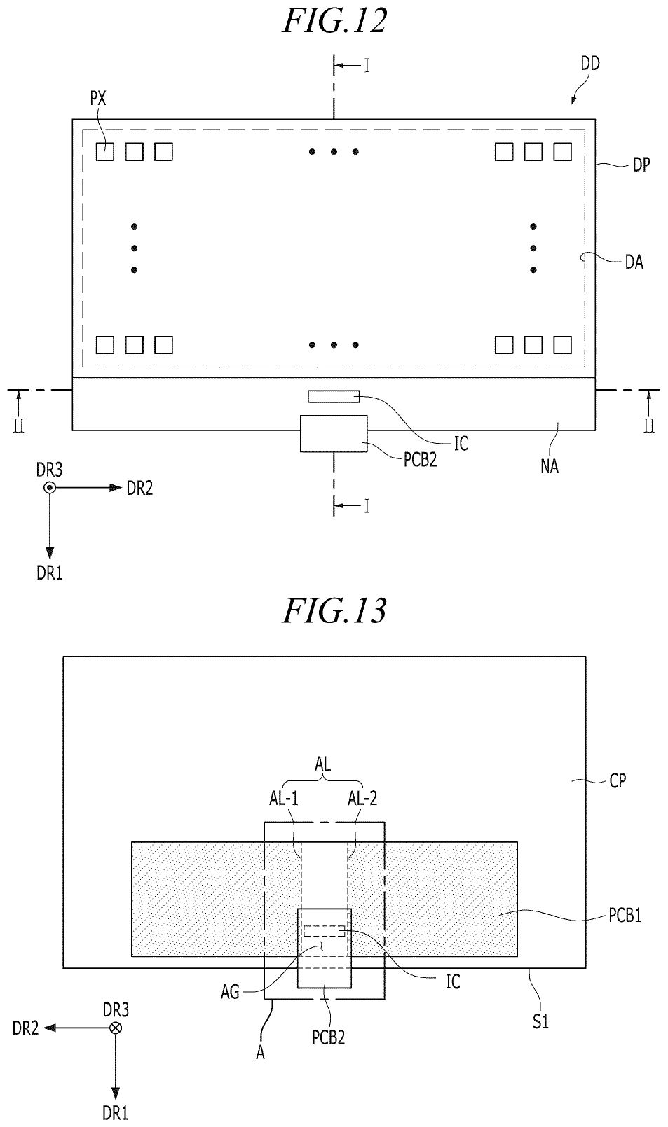

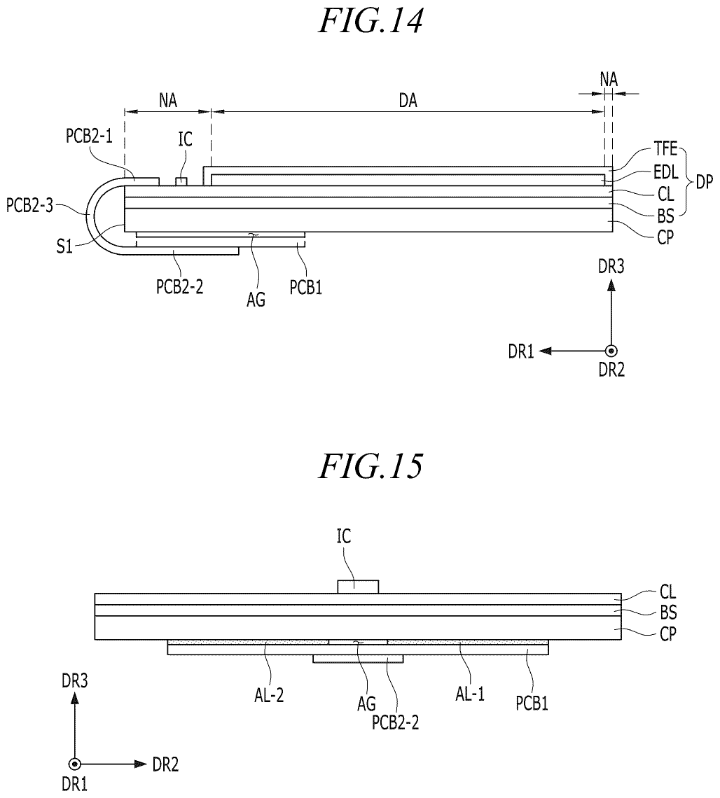

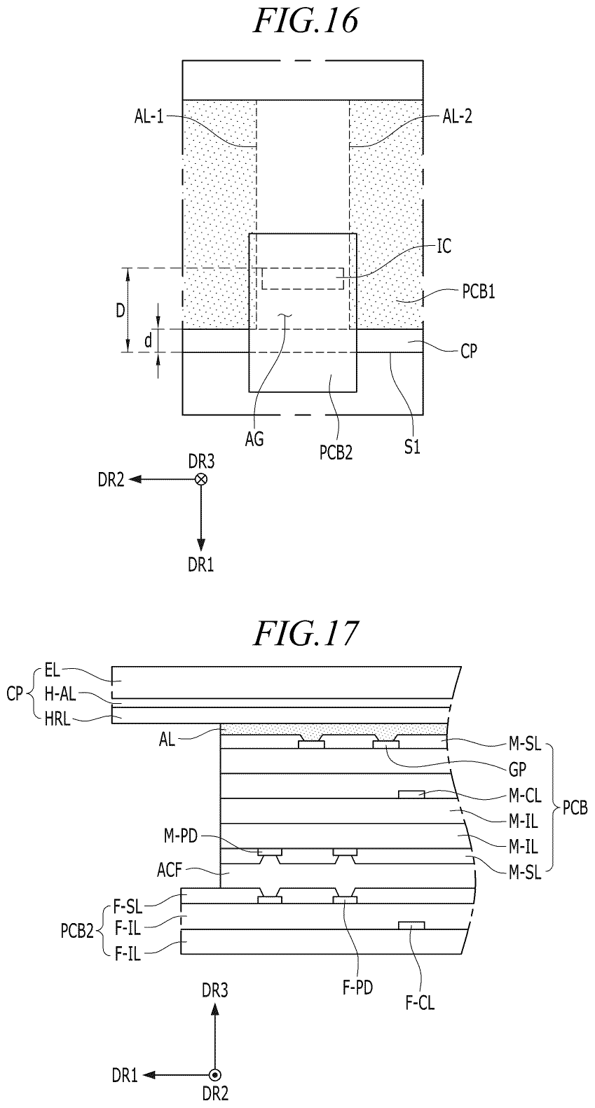

FIG. 12 is a plan view showing a display device according to some embodiments of the present disclosure; FIG. 13 is a bottom view of the display device shown in FIG. 12; FIG. 14 is a cross-sectional view taken along the line I-I of FIG. 12; FIG. 15 is a cross-sectional view taken along the line II-II of FIG. 12; and FIG. 16 is an enlarged view of portion A of FIG. 13. Referring to FIGS. 12 to 16, a display device DD according to some embodiments of the present disclosure may include a display panel DP, a cover panel CP, a driving chip IC, a first circuit board PCB1, an adhesive layer AL, and a second circuit board PCB2.

According to some embodiments, three directions DR1, DR2, DR3 may be defined. The first direction DR1 may be parallel to one side of the display panel DP, and the second direction DR2 may be intersecting the first direction DR1 and parallel to another side of the display panel DP. The third direction DR3 may be perpendicular to a surface of the display panel DP. In the context of the present embodiments, the expression “in a planar view” or “in a plan view” may refer to a view as seen from the third direction DR3.

The display panel DP may define a display area DA and a peripheral area NA. The display area DA is the region where an image is displayed, while the peripheral area NA surrounds the display area DA and where no image is displayed.

According to some embodiments, the display area DA is shown as a rectangular shape and to be surrounded by the peripheral area NA, but embodiments according to the present disclosure are not limited to what is illustrated herein, and the shapes of the display area DA and the peripheral area NA may be designed in various ways. Pixels PX, which are configured to generate images, may be arranged within the display area DA. Each pixel PX may include a light-emitting diode and a driving circuit configured to control the operation of the light-emitting diode. The light-emitting diode may include an organic light-emitting diode, and the driving circuit may include a thin-film transistor, but embodiments according to the present disclosure are not limited to this constitution.

The pixels PX may be arranged in a specific pattern and repeatedly placed within the display area DA. For example, the pixels PX may follow a Pentile™ arrangement, a Stripe arrangement, or a Diamond Pixel™ arrangement. Signal wiring configured to connect to the pixels PX may be located in the peripheral area NA. The signal wiring may include a data line connected to a source electrode of the thin-film transistor to provide a data signal, a gate line connected to a gate electrode of the thin-film transistor to provide a gate signal, and a power line connected to the light-emitting diode to apply voltage.

The display panel DP may include a substrate BS, a circuit layer CL, a display element layer EDL, and an encapsulation layer TFE. The substrate BS may be an element configured to provide a base surface on which the circuit layer CL is placed and may be made of glass, ceramic, metal, or polymer resins like polyimide. However, embodiments according to the present disclosure are not limited to what is described herein, and the substrate BS may be made of inorganic, organic, or composite materials, and may be configured with a single layer or multiple layers. The circuit layer CL may be placed on the substrate BS and may include the driving circuits of the pixels PX. The display element layer EDL may be located on the circuit layer CL and may include the light-emitting diodes of the pixels PX. The display area DA may be an area defined by the display element layer EDL in a planar view (e.g., in a plan view).

The encapsulation layer TFE may be located on the display element layer EDL to cover the display element layer EDL and to protect the light-emitting diodes of the display element layer EDL from moisture, oxygen, and/or foreign substances. The encapsulation layer TFE may include, but not limited to, a glass or synthetic resin substrate, and the encapsulation layer TFE may also be a layered structure constituted with inorganic and organic layers. According to some embodiments, additional layers such as a polarizing layer, input sensing unit, and/or cover window may be laminated on top of the encapsulation layer TFE.

The cover panel CP may be placed on a lower surface of the display panel DP. The cover panel CP may be configured to protect the display panel DP from external impacts and also to perform heat dissipating function. Detailed configurations of the cover panel CP will be described later. The driving chip IC may be mounted on an upper surface of the display panel DP and may overlap the peripheral area NA in a planar view (e.g., in a plan view). The driving chip IC may be electrically connected to the signal wiring of the display panel DP to provide data signals and/or gate signals to the display panel DP. The driving chip IC may include a source integrated circuit (Source IC) that is configured to provide data signals. The driving chip IC may further include, but not limited to, a timing controller (Tcon) and/or a level shifter. The driving chip IC may also be configured to provide electrical signals output from the display panel DP to the circuit boards PCB1, PCB2.

To facilitate signal transfer between the driving chip IC and the circuit boards PCB1, PCB2, the driving chip IC may overlap with the second circuit board PCB2 in the first direction DR1. The first circuit board PCB1 may be placed on a lower surface of the cover panel CP and connected to the display panel DP via the second circuit board PCB2. While the first circuit board PCB1 may be a rigid board, embodiments according to the present disclosure are not limited thereto. The first circuit board PCB1 may be electrically connected to the signal wiring of the display panel DP through the second circuit board PCB2 to provide control signals, power voltages, and the like to the display panel DP and/or the driving chip IC. The first circuit board PCB1 may include both active and passive devices and may have electronic components mounted thereon.

The adhesive layer AL may be located between the cover panel CP and the first circuit board PCB1. That is, the first circuit board PCB1 may be attached to the lower surface of the cover panel CP via the adhesive layer AL.

The second circuit board PCB2 may connect the upper surface of the display panel DP to the lower surface of the first circuit board PCB1. The second circuit board PCB2 may include a first portion PCB2-1, a second portion PCB2-2, and a third portion PCB2-3 and may be integrally formed with these portions. The first portion PCB2-1 may be located on the upper surface of the display panel DP and may overlap the peripheral area NA in a planar view (e.g., in a plan view). The second portion PCB2-2 may be placed on the lower surface of the first circuit board PCB1. The third portion PCB2-3, which may be curved, may connect the first portion PCB2-1 and the second portion PCB2-2. The third portion PCB2-3 may face a first side S1 of the cover panel CP in the first direction DR1. The second circuit board PCB2 may be a flexible board.

The adhesive layer AL may include a first portion AL-1 and a second portion AL-2, which are spaced apart from each other in the second direction DR2. As a result, an air gap AG defined by the first portion AL-1 and the second portion AL-2 of the adhesive layer AL may be provided between the cover panel CP and the first circuit board PCB1. The air gap AG may refer to a space filled with air. The air gap AG may extend to both ends of the first circuit board PCB1 in the first direction DR1. The air gap AG may overlap with at least a part of the driving chip IC in a planar view (e.g., in a plan view).

For example, a distance D from the first side S1 of the cover panel CP to a distal end of the driving chip IC in the first direction DR1 may be greater than a distance d from the first side S1 of the cover panel CP to the first circuit board PCB1 in the first direction DR1. Here, the distal end of the driving chip IC refers to an end farthest from the first side S1 of the cover panel CP in the first direction DR1. According to some embodiments, the air gap AG may be provided in a heat transfer path in the third direction DR3 from the first circuit board PCB1 to the driving chip IC. As a result, the heat generated by the first circuit board PCB1 is less likely to be transferred to the driving chip IC, thereby reducing the thermal load on the driving chip IC and relatively improving heat dissipation properties of the driving chip IC.

Moreover, thanks to the air gap AG provided between the cover panel CP and the first circuit board PCB1, it may be possible to relatively improve the reworkability, which is the ability to separate the first circuit board PCB1 from the cover panel CP. In some embodiments, the air gap AG may cover the driving chip IC in a planar view (e.g., in a plan view). In some embodiments, the driving chip IC may not overlap with the adhesive layer AL in a planar view (e.g., in a plan view). For example, the driving chip IC may be located between the first portion AL-1 and the second portion AL-2 in the second direction DR2 in a planar view (e.g., in a plan view).

According to some embodiments, although the second circuit board PCB2 is shown as partially overlapping with the first portion AL-1 and the second portion AL-2 of the adhesive layer AL in a planar view (e.g., in a plan view), embodiments according to the present disclosure are not limited to what is illustrated herein. The second circuit board PCB2 may also not overlap with the first portion AL-1 and the second portion AL-2 of the adhesive layer AL in a planar view (e.g., in a plan view). For the sake of description, FIGS. 13 and 16 represent the boundaries of the driving chip IC and the adhesive layer AL, which are not visible in the bottom view of the display device DD, as dotted lines.

According to some embodiments, while the display device DD is shown as including only one driving chip IC and one second circuit board PCB2, embodiments according to the present disclosure are not limited to what is illustrated herein. The display device DD may include multiple driving chips IC and multiple second circuit boards PCB2 corresponding to the multiple driving chips IC. In such a case, the driving chips IC may be spaced apart from each other in the second direction DR2. The driving chips IC may overlap, respectively, with the second circuit board PCB2 in the first direction DR1. The second circuit boards PCB2 may be connected to one or more first circuit boards PCB1. In such a case, the air gap AG may be provided as either multiple air gaps or a single air gap to overlap with each or all of the driving chips IC.

FIG. 17 illustrates the coupling structure between the cover panel, the first circuit board, and the second circuit board shown in FIG. 14. For the sake of description, both a first coupling structure between the cover panel CP and the first circuit board PCB1 and a second coupling structure between the first circuit board PCB1 and the second circuit board PCB2 are shown in a single cross-sectional view in FIG. 17, but the first coupling structure and the second coupling structure may be placed in different areas in a planar view (e.g., in a plan view).

Referring to FIG. 17, the cover panel CP may include a plurality of laminated layers EL, HRL, which may include an elastic layer EL and a heat-dissipating layer HRL. The elastic layer EL is configured to absorb external impact to protect the display panel DP from such external impacts. The elastic layer EL may include a foamed synthetic resin, for example, a foamed urethane sheet. The elastic layer EL may be placed on the lower surface of the display panel DP and may be attached to the lower surface of the display panel DP via an adhesive layer. The surface of the elastic layer EL may be provided with, but not limited to, micro-patterns (projections and/or grooves). The micro-patterns may provide a passage for air bubbles, which may form between the elastic layer EL and the display panel DP, to escape.

The heat-dissipating layer HRL may be configured to absorb heat generated from the display panel DP, the driving chip IC, and/or the first circuit board PCB1 and discharge the heat. Therefore, the heat dissipation characteristics can be relatively improved. The heat-dissipating layer HRL may include a metal material with excellent thermal conductivity. Here, the metal material may include copper, gold, silver, aluminum, and the like. However, embodiments according to the present disclosure are not limited to what is described herein, and the heat-dissipating layer HRL may also include a graphite layer instead of a metal layer.

The heat-dissipating layer HRL may be placed on a lower surface of the elastic layer EL and may be attached to the lower surface of the elastic layer EL via an adhesive layer H-AL. Additionally, according to some embodiments, the cover panel CP may further include a light-shielding layer. The light-shielding layer is configured to prevent or reduce penetration of external light into the display panel DP through a rear surface of the display panel DP. The light-shielding layer may include black-colored synthetic resin, for example, a PET film.

The heat-dissipating layer HRL may be electrically connected to a ground pad GP of the first circuit board PCB1 via the adhesive layer AL. The ground pad GP may be connected to a ground pattern of an electronic component mounted on the first circuit board PCB1 through a signal line M-CL. According to some embodiments, the adhesive layer AL may be an anisotropic conductive film. The heat-dissipating layer HRL may also function as a ground layer of the first circuit board PCB1.

According to some embodiments, the first circuit board PCB1 is shown as a six-layer circuit board, including four insulating layers M-IL and two solder resist layers M-SL, but this is merely an example, and the number of layers constituting the first circuit board PCB1 is not limited to this configuration. A connection pad M-PD of the first circuit board PCB1 and an input pad F-PD of the second circuit board PCB2 may also be electrically connected via the anisotropic conductive film ACF.

According to some embodiments, the second circuit board PCB2 is shown as a three-layer circuit board, including two insulating layers F-IL and one solder resist layer F-SL, but this is merely an example, and the number of layers constituting the second circuit board PCB2 is not limited to this configuration. According to some embodiments, an output pad of the second circuit board PCB2 and a connection pad of the display panel DP may also be electrically connected via the anisotropic conductive film.

The second circuit board PCB2 may include a signal line F-CL. The signal line F-CL may be configured to connect the output pad and the input pad F-PD of the second circuit board PCB2 and transfer electrical signals and power voltage between the display panel DP and/or the driving chip IC and the first circuit board PCB1.

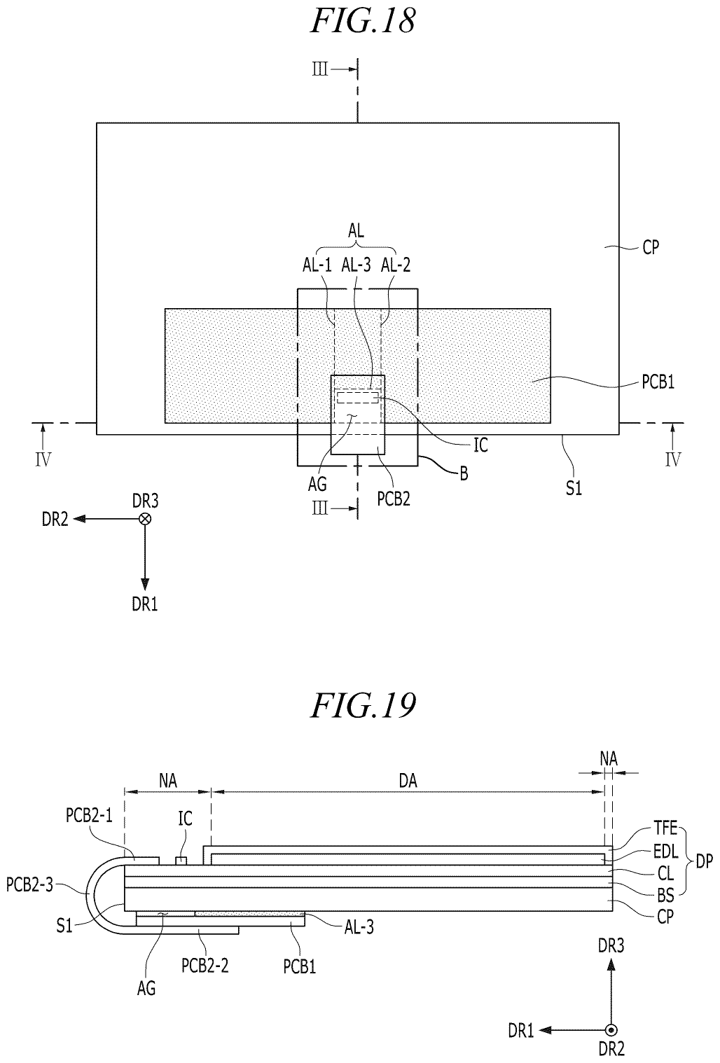

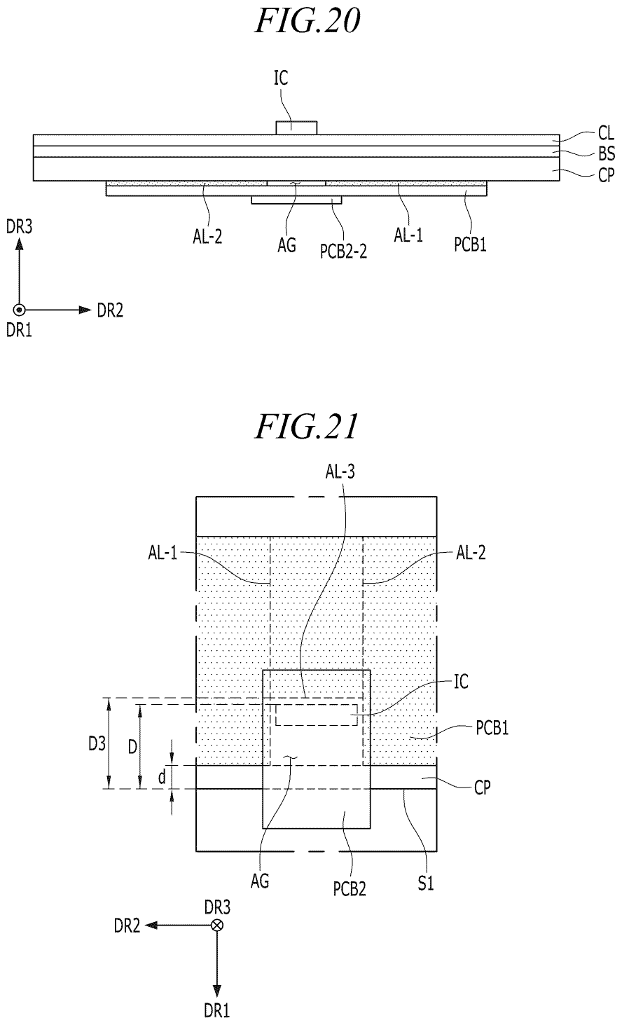

FIG. 18 is a modification example of FIG. 13; FIG. 19 is a cross-sectional view taken along the line III-III of FIG. 18; FIG. 20 is a cross-sectional view taken along the line IV-IV of FIG. 18; and FIG. 21 is an enlarged view of portion B of FIG. 18. Referring to FIGS. 18 to 21, the adhesive layer AL may further include a third portion AL-3 and may be integrally formed with the third portion AL-3. The third portion AL-3 may connect the first portion AL-1 and the second portion AL-2.

The third distance D3 from the first side S1 of the cover panel CP to the third portion AL-3 in the first direction DR1 may be greater than both the first distance from the first side S1 of the cover panel CP to the first portion AL-1 in the first direction DR1 and the second distance from the first side S1 of the cover panel CP to the second portion AL-2 in the first direction DR1. In this modification example, the air gap AG may be defined by the first portion AL-1, the second portion AL-2, and the third portion AL-3.

A first end of the air gap AG in the first direction DR1 may be closed off by the third portion AL-3 of the adhesive layer AL, and a second end of the air gap AG in the first direction DR1 may be connected to the outside of the adhesive layer AL. A distance D from the first side S1 of the cover panel CP to a distal end of the driving chip IC in the first direction DR1 may be smaller than the third distance D3. As a result, the driving chip IC may not overlap with the adhesive layer AL in a planar view (e.g., in a plan view).

In the meantime, the first distance from the first side S1 of the cover panel CP to the first portion AL-1 in the first direction DR1 and the second distance from the first side S1 of the cover panel CP to the second portion AL-2 in the first direction DR1 may be the same as the distance d from the first side S1 of the cover panel CP to the first circuit board PCB1 in the first direction DR1.

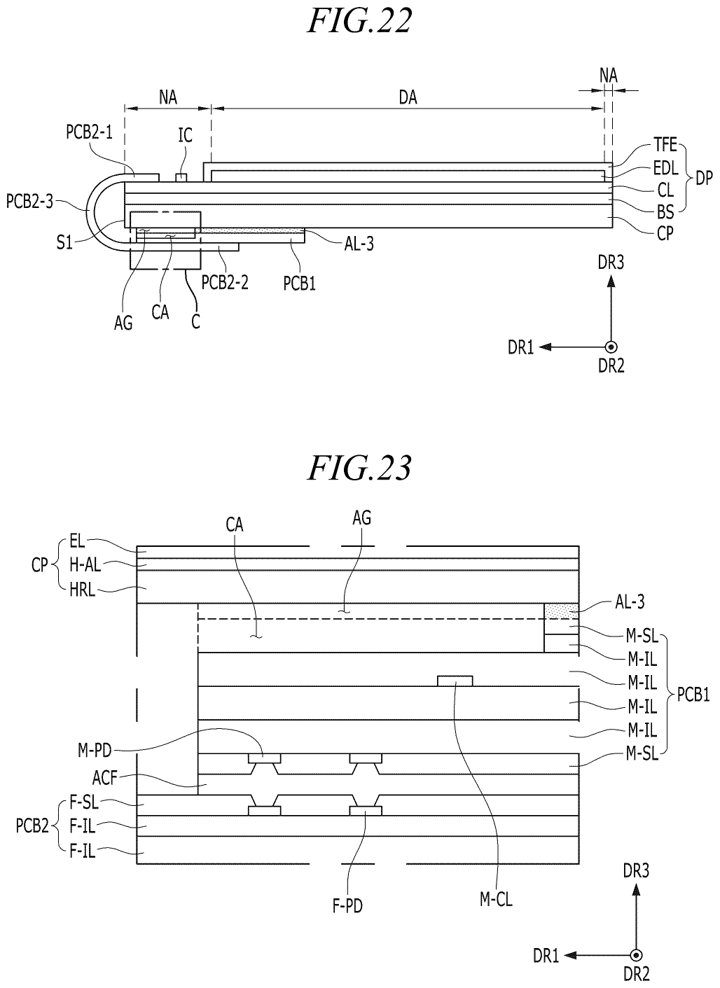

FIG. 22 is a modification example of FIG. 19, and FIG. 23 is an enlarged view of portion C of FIG. 22. Referring to FIGS. 22 and 23, the first circuit board PCB1 may include a plurality of laminated layers M-IL, M-SL. For example, the first circuit board PCB1 may include, but not limited to, four insulating layers M-IL and two solder resist layers M-SL.

Among the plurality of layers M-IL, M-SL of the first circuit board PCB1, upper layers adjacent to the lower surface of the cover panel CP, for example, one solder resist layer M-SL and one insulating layer M-IL, may be provided with a cut-out area CA. The cut-out area CA may overlap, in a planar view (e.g., in a plan view), with the remaining lower layers, for example, three insulating layers M-IL and one solder resist layer M-SL, of the plurality of layers M-IL, M-SL of the first circuit board PCB1 excluding the upper layers. The cut-out area CA may be defined by side surfaces of the upper layers and top surfaces of the lower layers.

The cut-out area CA may be directly connected to the air gap AG, and the cut-out area CA may be filled with air. The cut-out area CA may overlap with the air gap AG in a planar view (e.g., in a plan view). As a result, the air gap may be expanded by as much as the combined space of the air gap AG and the cut-out area CA.

The display device according to embodiments may be applied to various electronic devices. An electronic device according to some embodiments may include the above-described display device and may further include other additional modules or devices having additional functionalities.

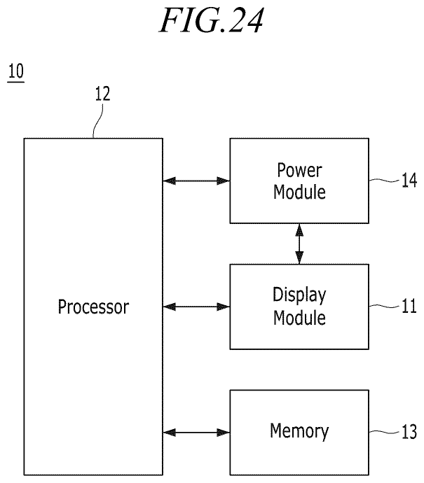

FIG. 24 is a block diagram of an electronic device according to some embodiments. Referring to FIG. 24, an electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may have data information necessary for the operation of the processor 12 or the display module 11 stored therein. When the processor 12 executes an application stored in the memory 13, image data signals and/or input control signals may be transferred to the display module 11, which then processes the provided signals and outputs image information through the display screen.

The power module 14 may include a power supply module, such as a power adapter or a battery device, and a power conversion module configured to convert the supplied power to generate the power required for the operation of the electronic device 10.

At least one of the components of the electronic device 10 described above may be included within the display device according to the described embodiments. Additionally, some of the individual modules functionally included in a single module may be integrated into the display device, while others may be provided separately from the display device. For example, the display device may include the display module 11, while the processor 12, the memory 13, and the power module 14 may be provided as components of another device within the electronic device 10.

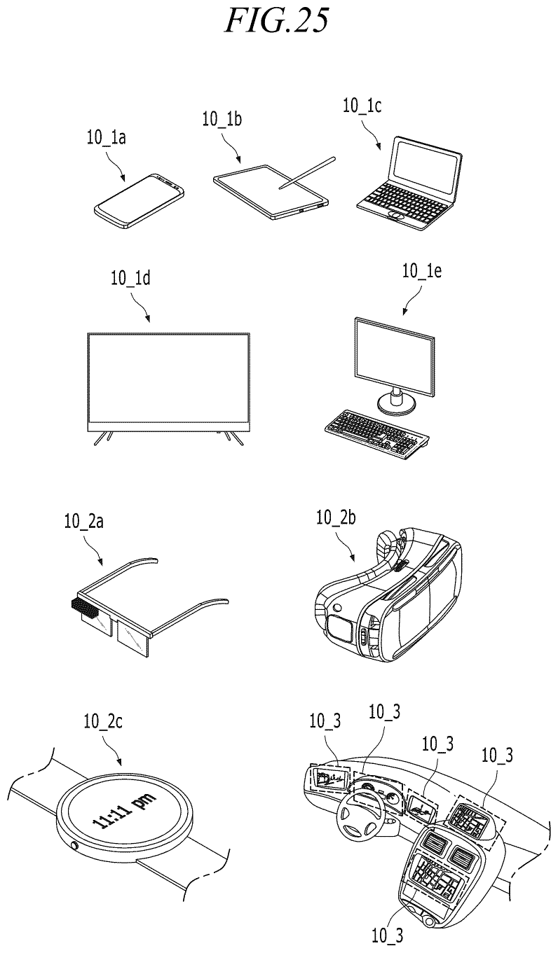

FIG. 25 shows schematic diagrams of various electronic devices according to various embodiments. Referring to FIG. 25, various electronic devices to which the display device according to the embodiments is applied may include image displaying electronic devices, such as a smartphone 10_1a, a tablet PC 10_1b, a laptop 10_1c, a TV 10_1d, or a desktop monitor 10_1e, as well as wearable electronic devices with a display module, such as smart glasses 10_2a, a head-mounted display 10_2b, or a smart watch 10_2c, and automotive electronic devices 10_3 having display modules, such as a center information display (CID), and a room mirror display, placed in an instrument panel, a center fascia or a dash board of a vehicle.

Aspects of some embodiments of the present disclosure have been described above, but these are merely examples and are not intended to limit scope of embodiments according to the present disclosure. Those skilled in the art to which the present disclosure pertains may make various modifications and changes to the embodiments by adding, changing, deleting, or adding certain elements, without departing from the scope of the technical ideas of the present disclosure as set forth in the claims, and such modifications and changes should also be regarded as being within the spirit and scope of embodiments according to the present disclosure.

What is claimed is:

1. A display device comprising:
a display panel with a display area and a peripheral area defined therein;
a cover panel on a lower surface of the display panel;
a driving chip on an upper surface of the display panel and overlapping the peripheral area in a plan view;
a first circuit board on a lower surface of the cover panel; and
a second circuit board connecting the display panel and the first circuit board,
wherein the cover panel comprises a side surface facing the second circuit board in a first direction,
wherein the first circuit board comprises a first portion connected to the second circuit board and a second portion connected to a first end of the first portion in a second direction intersecting the first direction,
wherein a first distance in the first direction from the side surface of the cover panel to the first portion is greater than a second distance in the first direction from the side surface of the cover panel to the second portion, and an air gap overlapping the first portion in the first direction and overlapping the second portion in the second direction is between the cover panel and the second circuit board, and
wherein at least a part of the driving chip overlaps the air gap in the plan view.

2. The display device of claim 1, wherein a distance in the first direction from the side surface of the cover panel to a distal end of the driving chip is smaller than the first distance and greater than the second distance, the distal end of the driving chip being farthest from the side surface of the cover panel.

3. The display device of claim 2, wherein a portion of a boundary of the air gap is defined by the first portion and the second portion.

4. The display device of claim 2, wherein the driving chip is spaced apart from the second portion in the second direction in the plan view.

5. The display device of claim 2, wherein the second circuit board is spaced apart from the second portion in the second direction in the plan view, and
wherein a lower surface of the cover panel is exposed between the second circuit board and the second portion.

6. The display device of claim 2, wherein the first circuit board further comprises a third portion connected to a second end of the first portion in the second direction, and
wherein a third distance in the first direction from the side surface of the cover panel to the third portion is smaller than the first distance.

7. The display device of claim 6, wherein a portion of a boundary of the air gap is defined by the first portion, the second portion, and the third portion.

8. The display device of claim 6, wherein the driving chip is between the second portion and the third portion in the second direction in the plan view.

9. The display device of claim 6, wherein the second circuit board is between the second portion and the third portion in the second direction in the plan view, and
wherein the lower surface of the cover panel is exposed between the second circuit board and the second portion and between the second circuit board and the third portion.

10. The display device of claim 6, wherein the third distance is equal to the second distance.

11. The display device of claim 1, further comprising an adhesive layer between the cover panel and the first circuit board.

12. The display device of claim 11, wherein the cover panel comprises a plurality of laminated layers, and
wherein a layer of the plurality of laminated layers adjacent to the adhesive layer comprises a metal material.

13. A display device comprising:
a display panel with a display area and a peripheral area defined therein;
a cover panel on a lower surface of the display panel;
a driving chip on an upper surface of the display panel and overlapping with the peripheral area in a plan view;
a first circuit board on a lower surface of the cover panel;
a adhesive layer between the cover panel and the first circuit board; and
a second circuit board connecting the display panel and the first circuit board,
wherein the cover panel comprises a side surface facing the second circuit board in a first direction,
wherein the adhesive layer comprises a first portion and a second portion spaced apart from each other in a second direction intersecting the first direction,
wherein an air gap overlapping with the first portion and the second portion in the second direction is provided between the cover panel and the first circuit board, and
wherein at least a part of the driving chip overlaps with the air gap in the plan view.

14. The display device of claim 13, wherein a distance in the first direction from the side surface of the cover panel to a distal end of the driving chip is greater than a distance in the first direction from the side surface of the cover panel to the first circuit board, the distal end of the driving chip being farthest from the side surface of the cover panel.

15. The display device of claim 14, wherein the air gap extends to both ends of the first circuit board in the first direction.

16. The display device of claim 14, wherein the driving chip is between the first portion and the second portion in the second direction in the plan view.

17. The display device of claim 14, wherein the adhesive layer further comprises a third portion connecting the first portion and the second portion,
wherein a third distance in the first direction from the side surface of the cover panel to the third portion is greater than a first distance from the side surface of the cover panel to the first portion in the first direction and a second distance from the side surface of the cover panel to the second portion in the first direction, and
wherein the air gap overlaps the third portion in the first direction.

18. The display device of claim 17, wherein a distance in the first direction from the side surface of the cover panel to the distal end of the driving chip is smaller than the third distance.

19. The display device of claim 13, wherein the cover panel comprises a plurality of laminated layers, and
wherein a layer of the plurality of laminated layers adjacent to the adhesive layer comprises a metal material.

20. An electronic device comprising:
a display panel with a display area and a peripheral area defined therein;
a cover panel on a lower surface of the display panel;
a driving chip on an upper surface of the display panel and overlapping with the peripheral area in a plan view;
a first circuit board on a lower surface of the cover panel; and
a second circuit board connecting the display panel and the first circuit board,
wherein the cover panel comprises a side surface facing the second circuit board in a first direction,
wherein the first circuit board comprises a first portion connected to the second circuit board and a second portion connected to a first end of the first portion in a second direction intersecting the first direction,
wherein a first distance in the first direction from the side surface of the cover panel to the first portion is greater than a second distance in the first direction from the side surface of the cover panel to the second portion, and an air gap overlapping with the first portion in the first direction and overlapping with the second portion in the second direction is between the cover panel and the second circuit board, and
wherein at least a part of the driving chip overlaps with the air gap in the plan view.
